(19) United States
(12) Patent Application Publication
(10) Pub. No.: US 2008/0135914 A1
(43) Pub. Date: Jun. 12, 2008

(54) NANOCRYSTAL FORMATION

(76) Inventors: Nety M. Krishna, Sunnyvale, CA (US); Ralf Hofmann, Soquel, CA (US); Kaushal K. Singh, Santa Clara, CA (US); Karl J. Armstrong, San Jose, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/771,778

(22) Filed: Jun. 29, 2007

Related U.S. Application Data
(60) Provisional application No. 60/806,446, filed on Jun. 30, 2006.

(51) Int. Cl. H01L 21/28; H01L 29/788

(52) U.S. Cl. 257/316; 438/594; 257/E21.158; 257/E29.3

(57) ABSTRACT

In one embodiment, a method for forming a metallic nanocrystalline material on a substrate is provided which includes exposing a substrate to a pretreatment process, forming a tunnel dielectric layer on the substrate, exposing the substrate to a post-treatment process, forming a metallic nanocrystalline layer on the tunnel dielectric layer, and forming a dielectric capping layer on the metallic nanocrystalline layer. The method further provides forming the metallic nanocrystalline layer having a nanocrystalline density of at least about 5×10¹² cm⁻², preferably, at least about 8×10¹² cm⁻². In one example, the metallic nanocrystalline layer contains platinum, ruthenium, or nickel. In another embodiment, a method for forming a multi-layered metallic nanocrystalline material on a substrate is provided which includes forming a plurality of bi-layers, wherein each bi-layer contains an intermediate dielectric layer deposited on a metallic nanocrystalline layer. Some of the examples include 10, 50, 100, 200, or more bi-layers.

### CROSS-REFERENCE TO RELATED APPLICATION

This application claims benefit of U.S. Ser. No. 60/806,446 (APPM/11087L), filed Jun. 30, 2006, which is herein incorporated by reference in its entirety.

### BACKGROUND OF THE INVENTION

1. Field of the Invention

The invention generally relates to nanocrystals and nanocrystalline materials, as well as the processes for forming nanocrystals and nanocrystalline materials.

2. Description of the Relted Art

Nanotechnology has become a popular field of science with applications in many industries. Nanocrystalline materials, a species of nanotechnology, have been developed and utilized for all sorts of applications, such as fuel cells catalysts, battery catalysts, polymerization catalysts, catalytic converters, photovoltaic cells, light emitting devices, energy scavenger devices, and recently, flash memory devices. Often, the nanocrystalline materials contain multiple nanocrystals or nanodots of a noble metal, such as platinum or palladium.

Flash memory devices for storing and transferring digital data are found in many consumer products. Flash memory devices are used by computers, digital assistants, digital cameras, digital audio recorders and players, and cellular telephones. Silicon-based flash memory devices generally contain multiple layers of different crystallinity or doped materials of silicon, silicon oxide, and silicon nitride. These silicon-based devices are usually very thin and are simple to fabricate, but are susceptible to complete failure with only slight damage.

FIGS. 1A-1B depict a typical silicon-based flash memory device, as described by the prior art. Flash memory cell 100 is disposed on substrate 102 (e.g., silicon substrate) which contains source region 104, drain region 106, and channel region 108, as illustrated in FIG. 1. Flash memory cell 100 further contains tunnel dielectric layer 110 (e.g., oxide), floating gate layer 120 (e.g., silicon nitride), top dielectric layer 130 (e.g., silicon oxide), and control gate layer 140 (e.g., polysilicon layer). While charge-trapping site in floating gate layer 120 can capture electrons or holes penetrating tunnel dielectric layer 110, top dielectric layer 130 serves to prevent electrons and holes from escaping floating gate layer 120 to enter into control gate layer 140 during writing or erasing operations of the flash memory. The electrons follow along charge path 122 from source region 104 towards drain region 106.

FIG. 1B depicts flash memory cell 100 subsequent the formation of defect 115, generally formed within tunnel dielectric layer 110. Defect 115 usually disrupts the electron flow along charge path 122 to cause complete charge loss between source region 104 and drain region 106. Since different threshold voltages represent different data bits stored by flash memory cell 100, a disruption of charge path 122 by defect 115 may cause the loss of stored data. Some researchers have been working to solve this problem by using different types of materials for tunnel dielectric layer 110.

Therefore, a need exists for a method for forming nanocrystalline materials for use in flash memory devices as well as other devices.

### SUMMARY OF THE INVENTION

Embodiments of the invention provide metallic nanocrystalline materials, devices that utilize these materials, as well as the methods to form the metallic nanocrystalline materials. In one embodiment, a method for forming a metallic nanocrystalline material on a substrate is provided which includes exposing a substrate to a pretreatment process, forming a tunnel dielectric layer on the substrate, exposing the substrate to a post-treatment process, forming a metallic nanocrystalline layer on the tunnel dielectric layer, and forming a dielectric capping layer on the metallic nanocrystalline layer. The method further provides forming the metallic nanocrystalline layer having a nanocrystalline density of at least about 5×10¹² cm⁻², preferably, of at least about 8×10¹² cm⁻². In one example, the metallic nanocrystalline layer contains platinum, palladium, nickel, iridium, ruthenium, cobalt, tungsten, tantalum, molybdenum, rhodium, gold, suicides thereof, nitrides thereof, carbides thereof, alloys thereof, or combinations thereof. In another example, the metallic nanocrystalline layer contains platinum, ruthenium, nickel, alloys thereof, or combinations thereof. In another example, the metallic nanocrystalline layer contains ruthenium or a ruthenium alloy.

In another embodiment, a method for forming a multi-layered metallic nanocrystalline material on a substrate is provided which includes exposing a substrate to a pretreatment process, forming a tunnel dielectric layer on the substrate, forming a first metallic nanocrystalline layer on the tunnel dielectric layer, forming an intermediate dielectric layer on the first metallic nanocrystalline layer, forming a second metallic nanocrystalline layer on the intermediate dielectric layer, and forming a dielectric capping layer on the second metallic nanocrystalline layer.

In another embodiment, a method for forming a multi-layered metallic nanocrystalline material on a substrate is provided which includes exposing a substrate to a pretreatment process, forming a tunnel dielectric layer on the substrate, forming a plurality of bi-layers on the substrate, wherein each of the bi-layers comprises an intermediate dielectric layer deposited on a metallic nanocrystalline layer, and forming a dielectric capping layer on the plurality of bi-layers. In one example, the plurality of bi-layers may contain at least 10 metallic nanocrystalline layers and at least 10 intermediate dielectric layers. In another example, the plurality of bi-layers may contain at least 50 metallic nanocrystalline layers and at least 50 intermediate dielectric layers. In another example, the plurality of bi-layers may contain at least 100 metallic nanocrystalline layers and at least 100 intermediate dielectric layers.

In one embodiment, a metallic nanocrystalline material is provided which includes a tunnel dielectric layer disposed on a substrate, a first metallic nanocrystalline layer disposed on the tunnel dielectric layer, a first intermediate dielectric layer disposed on the first metallic nanocrystalline layer, a second metallic nanocrystalline layer disposed on the first intermediate dielectric layer, a second intermediate dielectric layer disposed on the second metallic nanocrystalline layer, a third metallic nanocrystalline layer disposed on the second intermediate dielectric layer, and a dielectric capping layer disposed on the third metallic nanocrystalline layer.

In another embodiment, the method further provides exposing the metallic nanocrystalline layer to a rapid thermal annealing process (RTA) to control the nanocrystalline size and size distribution. The metallic nanocrystalline layer may be formed at a temperature within a range from 300° C. to about 1,250° C. during the RTA process. In some examples, the temperature may be within a range from 400° C. to about 1,100° C. or from 500° C. to about 1,000° C. In the metallic nanocrystalline layer, at least about 80% by weight of the nanocrystals have a nanocrystalline grain size within a range from about 1 nm to about 5 nm. In other examples, at least about 90%, 95%, or 99% by weight of the nanocrystals have the nanocrystalline grain size within the range from about 1 nm to about 5 nm. The method further provides forming the metallic nanocrystalline layer by a vapor deposition process, such as atomic layer deposition (ALD), chemical vapor deposition (CVD), physical vapor deposition (PVD), or by a liquid deposition process, such as electroless deposition or electrochemical plating (ECP).

The method further provides forming a hydrophobic surface on the substrate during the pretreatment process. The hydrophobic surface may be formed by exposing the substrate to a reducing agent, such as silane, disilane, ammonia, hydrazine, diborane, triethylborane, hydrogen, atomic hydrogen, or plasmas thereof. The method may also provide exposing the substrate to a degassing process during the pretreatment process. Alternatively, the method may provide forming a nucleation surface or a seed surface on the substrate during the pretreatment process. The nucleation surface or the seed surface may be formed by ALD, P3i flooding, or charge gun flooding.

In another aspect, the method further provides forming the tunnel dielectric layer on the substrate with a uniformity of less than about 0.5%. The tunnel dielectric layer may be formed by pulsed DC deposition, RF sputtering, electroless deposition, ALD, CVD, or PVD. The method further provides exposing the substrate to RTA, laser annealing, doping, P3i flooding, or CVD during the post-treatment process. In one example, a sacrificial capping layer may be deposited on the substrate during the post-treatment process. The sacrificial capping layer may be deposited by a spin-on process, electroless deposition, ALD, CVD, or PVD.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1B depict a schematic cross-sectional view of a flash memory device as described in the prior art;

FIGS. 2A-2B depict a schematic cross-sectional view of a flash memory device according to embodiments described herein;

FIG. 3 depicts a schematic cross-sectional view of another flash memory device according to other embodiments described herein; and

FIG. 4 depicts a schematic cross-sectional view of another flash memory device according to other embodiments described herein.

### DETAILED DESCRIPTION

Embodiments of the invention provide metallic nanocrystals and nanocrystalline materials containing the metallic nanocrystals, as well as processes for forming the metallic nanocrystals and the nanocrystalline materials. Metallic nanocrystals and the nanocrystalline materials, as described herein, may be used in semiconductor and electronics devices (e.g., flash memory devices, photovoltaic cells, light emitting devices, and energy scavenger devices), biotechnology, and in many processes that utilize a catalyst, such as fuel cell catalysts, battery catalysts, polymerization catalysts, or catalytic converters. In one example, metallic nanocrystals may be used to form a non-volatile memory device, such as NAND flash memory.

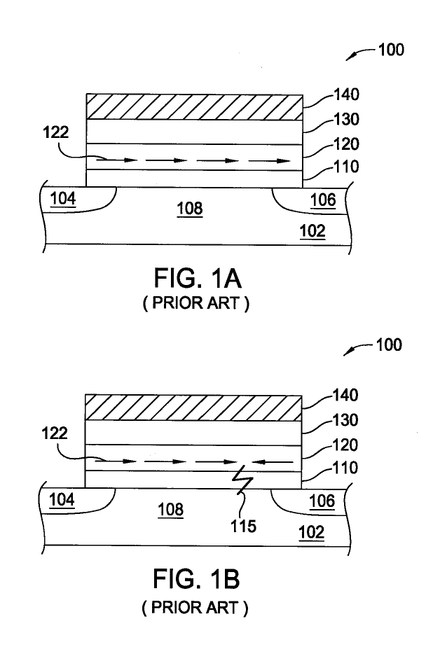

FIG. 1B depicts flash memory cell 100 having defect 115, as described by the prior art. Defect 115 usually forms in tunnel dielectric layer 110 and renders the typical silicon-based flash memory device useless, since the disruption of charge path 122 causes the loss of stored data.

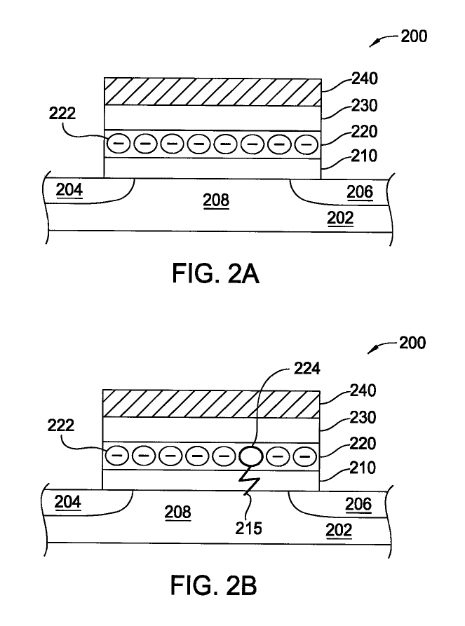

FIG. 2A depicts flash memory cell 200 is disposed on substrate 202 which contains source region 204, drain region 206, and channel region 208. Flash memory cell 200 further contains tunnel dielectric layer 210 (e.g., silicon oxide), nanocrystal layer 220, top dielectric layer 230 (e.g., silicon oxide), and control gate layer 240 (e.g., polysilicon layer). Nanocrystal layer 220 contains a plurality of metallic nanocrystals 222 (e.g., ruthenium, platinum, or nickel). Since each metallic nanocrystal 222 can hold an individual charge, electrons flow along a charge path within nanocrystal layer 220 from source region 204 towards drain region 206. Charge-trapping nanocrystals 222 within nanocrystal layer 220 capture electrons or holes penetrating tunnel dielectric layer 210, while top dielectric layer 230 serves to prevent electrons and holes from escaping nanocrystal layer 220 to enter into control gate layer 240 during writing or erasing operations of the flash memory.

FIG. 2B depicts flash memory cell 200 subsequent the formation of defect 215, generally formed within tunnel dielectric layer 210. However, unlike defect 115 of flash memory cell 100, defect 215 of flash memory cell 200 does not disrupt the electron flow along the charge path between source region 204 and drain region 206 within nanocrystal layer 220. Only the charge of individual nanocrystals near defect 215 is lost, such as nanocrystal 224. Therefore, flash memory cell 200 loses only a partial of the overall stored charge, while the charge path still exists between source region 204 and drain region 206 within nanocrystal layer 220. Furthermore, since flash memory cell 200 does not experience a disruption of the charge path by defect 215, stored data is not lost.

Embodiments herein provide methods that may be used to form flash memory cell 200, as depicted in FIG. 2A. In one embodiment, a method for forming a metallic nanocrystalline material on a substrate is provided which includes exposing the substrate to a pretreatment process, forming a tunnel dielectric layer on the substrate, exposing the substrate to a post-treatment process, forming a metallic nanocrystalline layer on the tunnel dielectric layer, forming a dielectric capping layer on the metallic nanocrystalline layer, and exposing the substrate to a metrological process. In another embodiment, a method for forming a metallic nanocrystalline material on a substrate is provided which includes exposing the substrate to a pretreatment process, forming a tunnel dielectric layer on the substrate, forming a metallic nanocrystalline layer on the tunnel dielectric layer, forming a dielectric capping layer on the metallic nanocrystalline layer, and exposing the substrate to a metrological process. In another embodiment, a method for forming a metallic nanocrystalline material on a substrate is provided which includes exposing the substrate to a pretreatment process, forming a tunnel dielectric layer on the substrate, exposing the substrate to a post-treatment process, forming a metallic nanocrystalline layer on the tunnel dielectric layer, and forming a dielectric capping layer on the metallic nanocrystalline layer. In another embodiment, a method for forming a metallic nanocrystalline material on a substrate is provided which includes exposing the substrate to a pretreatment process, forming a tunnel dielectric layer on the substrate, exposing the substrate to a post-treatment process, forming a metallic nanocrystalline layer on the tunnel dielectric layer, forming a dielectric capping layer on the metallic nanocrystalline layer, and forming a control gate layer on the dielectric capping layer. Embodiments provide that metallic nanocrystals 222 may contain at least one metal such as platinum, palladium, nickel, iridium, ruthenium, cobalt, tungsten, tantalum, molybdenum, rhodium, gold, silicides thereof, nitrides thereof, carbides thereof, alloys thereof, and combinations thereof.

Embodiments herein provide methods that may be used to form flash memory cells having two or more bi-layers of metallic nanocrystalline layers and dielectric layers. In one embodiment, a method for forming a multi-layered metallic nanocrystalline material on a substrate is provided which includes exposing the substrate to a pretreatment process, forming a tunnel dielectric layer on the substrate, exposing the substrate to a post-treatment process, forming a first metallic nanocrystalline layer on the tunnel dielectric layer, forming an intermediate dielectric layer on the first metallic nanocrystalline layer, forming a second metallic nanocrystalline layer on the intermediate dielectric layer, forming a dielectric capping layer on the second metallic nanocrystalline layer, and exposing the substrate to a metrological process. In another embodiment, a method for forming a multi-layered metallic nanocrystalline material on a substrate is provided which includes exposing the substrate to a pretreatment process, forming a tunnel dielectric layer on the substrate, forming a first metallic nanocrystalline layer on the tunnel dielectric layer, forming an intermediate dielectric layer on the first metallic nanocrystalline layer, forming a second metallic nanocrystalline layer on the intermediate dielectric layer, forming a dielectric capping layer on the second metallic nanocrystalline layer, and exposing the substrate to a metrological process. In another embodiment, a method for forming a multi-layered metallic nanocrystalline material on a substrate is provided which includes exposing the substrate to a pretreatment process, forming a tunnel dielectric layer on the substrate, forming a first metallic nanocrystalline layer on the tunnel dielectric layer, forming an intermediate dielectric layer on the first metallic nanocrystalline layer, forming a second metallic nanocrystalline layer on the intermediate dielectric layer, forming a dielectric capping layer on the second metallic nanocrystalline layer, and exposing the substrate to a metrological process. In another embodiment, a method for forming a multi-layered metallic nanocrystalline material on a substrate is provided which includes exposing the substrate to a pretreatment process, forming a tunnel dielectric layer on the substrate, exposing the substrate to a post-treatment process, forming a first metallic nanocrystalline layer on the tunnel dielectric layer, forming an intermediate dielectric layer on the first metallic nanocrystalline layer, forming a second metallic nanocrystalline layer on the intermediate dielectric layer, and forming a dielectric capping layer on the second metallic nanocrystalline layer. In another embodiment, a method for forming a multi-layered metallic nanocrystalline material on a substrate is provided which includes forming a tunnel dielectric layer on the substrate, exposing the substrate to a post-treatment process, forming a first metallic nanocrystalline layer on the tunnel dielectric layer, forming an intermediate dielectric layer on the first metallic nanocrystalline layer, forming a second metallic nanocrystalline layer on the intermediate dielectric layer, forming a dielectric capping layer on the second metallic nanocrystalline layer, and forming a control gate layer on the dielectric capping layer.

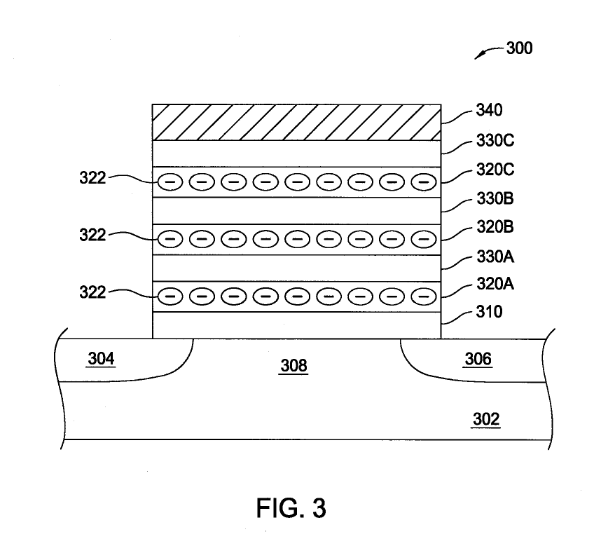

FIG. 3 depicts flash memory cell 300 disposed on substrate 302 that contains source region 304, drain region 306, and channel region 308. Tunnel dielectric layer 310 is formed over source region 304, drain region 306, and channel region 308 as part of flash memory cell 300. Nanocrystal layers 320A, 320B, and 320C containing a plurality of metallic nanocrystals 322 are sequentially stacked with intermediate dielectric layers 330A, 330B, and 330C, as illustrated in FIG. 3. Control gate layer 340 is disposed on intermediate dielectric layer 330C.

Embodiments herein provide methods that may be used to form flash memory cell 300, as depicted in FIG. 3. In one embodiment, a method for forming a multi-layered metallic nanocrystalline material on a substrate is provided which includes exposing the substrate to a pretreatment process, forming a tunnel dielectric layer (e.g., tunnel dielectric layer 310) on the substrate, exposing the substrate to a post-treatment process, forming a first metallic nanocrystalline layer (e.g., nanocrystal layer 320A) on the tunnel dielectric layer, forming a first intermediate dielectric layer (e.g., intermediate dielectric layer 330A) on the first metallic nanocrystalline layer, forming a second metallic nanocrystalline layer (e.g., nanocrystal layer 320B) on the first intermediate dielectric layer, forming a second intermediate dielectric layer (e.g., intermediate dielectric layer 330B) on the second metallic nanocrystalline layer, forming a third metallic nanocrystalline layer (e.g., nanocrystal layer 320C) on the second intermediate dielectric layer, forming a dielectric capping layer (e.g., intermediate dielectric layer 330C) on the third metallic nanocrystalline layer, and exposing the substrate to a metrological process. A control gate layer (e.g., control gate layer 340) may be deposited on the dielectric capping layer.

In another embodiment, a method for forming a multi-layered metallic nanocrystalline material on a substrate is provided which includes exposing the substrate to a pretreatment process, forming a tunnel dielectric layer on the substrate, forming a first metallic nanocrystalline layer on the tunnel dielectric layer, forming a first intermediate dielectric layer on the first metallic nanocrystalline layer, forming a second metallic nanocrystalline layer on the first intermediate dielectric layer, forming a second intermediate dielectric layer on the second metallic nanocrystalline layer, forming a third metallic nanocrystalline layer on the second intermediate dielectric layer, forming a dielectric capping layer on the third metallic nanocrystalline layer, and exposing the substrate to a metrological process.

In another embodiment, a method for forming a multi-layered metallic nanocrystalline material on a substrate is provided which includes exposing the substrate to a pretreatment process, forming a tunnel dielectric layer on the substrate, forming a first metallic nanocrystalline layer on the tunnel dielectric layer, forming a first intermediate dielectric layer on the first metallic nanocrystalline layer, forming a second metallic nanocrystalline layer on the first intermediate dielectric layer, forming a second intermediate dielectric layer on the second metallic nanocrystalline layer, forming a third metallic nanocrystalline layer on the second intermediate dielectric layer, forming a dielectric capping layer on the third metallic nanocrystalline layer, and exposing the substrate to a metrological process.

In another embodiment, a method for forming a multi-layered metallic nanocrystalline material on a substrate is provided which includes exposing the substrate to a pretreatment process, forming a tunnel dielectric layer on the substrate, exposing the substrate to a post-treatment process, forming a first metallic nanocrystalline layer on the tunnel dielectric layer, forming a first intermediate dielectric layer on the first metallic nanocrystalline layer, forming a second metallic nanocrystalline layer on the first intermediate dielectric layer, forming a second intermediate dielectric layer on the second metallic nanocrystalline layer, forming a third metallic nanocrystalline layer on the second intermediate dielectric layer, and forming a dielectric capping layer on the third metallic nanocrystalline layer.

In another embodiment, a method for forming a multi-layered metallic nanocrystalline material on a substrate is provided which includes forming a tunnel dielectric layer on the substrate, exposing the substrate to a post-treatment process, forming a first metallic nanocrystalline layer on the tunnel dielectric layer, forming a first intermediate dielectric layer on the first metallic nanocrystalline layer, forming a second metallic nanocrystalline layer on the first intermediate dielectric layer, forming a second intermediate dielectric layer on the second metallic nanocrystalline layer, forming a third metallic nanocrystalline layer on the second intermediate dielectric layer, forming a dielectric capping layer on the third metallic nanocrystalline layer, and forming a control gate layer on the dielectric capping layer.

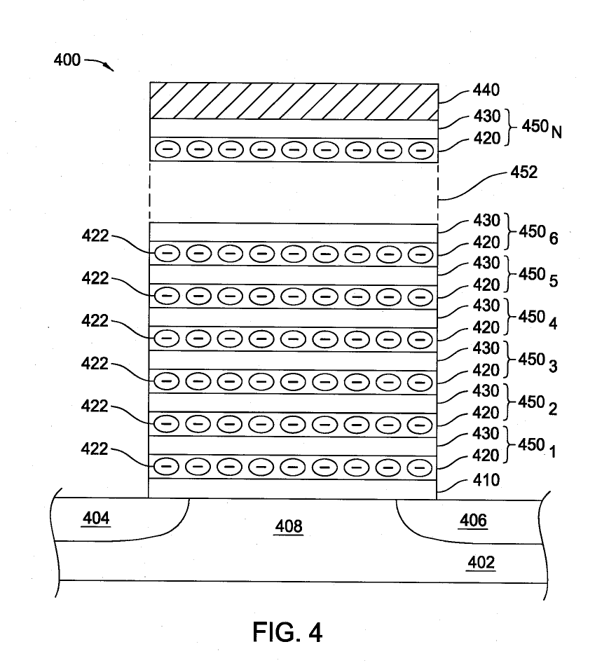

FIG. 4 depicts flash memory cell 400 disposed on substrate 402 that contains source region 404, drain region 406, and channel region 408. Tunnel dielectric layer 410 is formed over source region 404, drain region 406, and channel region 408 as part of flash memory cell 400. Nanocrystal layers 420 containing a plurality of metallic nanocrystals 422 are sequentially stacked with intermediate dielectric layers 430, as illustrated in FIG. 4. Each bi-layer 450, from bi-layer 450₁ through bi-layer 450_{N}, contains a nanocrystal layer 420 and an intermediate dielectric layer 430. Control gate layer 440 is disposed on intermediate dielectric layer 430 of bi-layer 450_{N}.

Region 452, between bi-layer 450₆ and bi-layer 450_{N} may contain no bi-layers 450 or may contain several hundred bi-layers 450. In one example, region 452 does not contain a bi-layer 450, therefore, N=7 for bi-layer 450_{N} and flash memory cell 400 contains a total of 7 bi-layers 450. In another example, region 452 contains 3 additional bi-layers 450 (not shown), therefore, N=10 for bi-layer 450_{N} and flash memory cell 400 contains a total of 10 bi-layers 450. In another example, region 452 contains 43 additional bi-layers 450 (not shown), therefore, N=50 for bi-layer 450_{N} and flash memory cell 400 contains a total of 50 bi-layers 450. In another example, region 452 contains 93 additional bi-layers 450 (not shown), therefore, N=100 for bi-layer 450_{N} and flash memory cell 400 contains a total of 100 bi-layers 450. In another example, region 452 contains 193 additional bi-layers 450 (not shown), therefore, N=200 for bi-layer 450_{N} and flash memory cell 400 contains a total of 200 bi-layers 450.

Flash memory cell 400 may have several hundred bi-layers 450 within a multi-layered metallic nanocrystalline material, as depicted in FIG. 4. In one embodiment, a method for forming a multi-layered metallic nanocrystalline material on a substrate is provided which includes exposing the substrate to a pretreatment process, forming a tunnel dielectric layer on the substrate, forming a plurality of bi-layers on the substrate, wherein each of the bi-layers comprises an intermediate dielectric layer deposited on a metallic nanocrystalline layer, and forming a dielectric capping layer on the plurality of bi-layers. In one example, the plurality of bi-layers may contain at least 10 metallic nanocrystalline layers and at least 10 intermediate dielectric layers. In another example, the plurality of bi-layers may contain at least 50 metallic nanocrystalline layers and at least 50 intermediate dielectric layers. In another example, the plurality of bi-layers may contain at least 100 metallic nanocrystalline layers and at least 100 intermediate dielectric layers.

The substrate surface may be pretreated to have a smooth surface to prevent non-uniform nucleation. In one embodiment, a variety of dielectric steps and finishing steps are used to form a desirable substrate surface. In some examples, the pretreatment process may provide a smooth surface having a uniformity of about 2 Å to about 3 Å. In another embodiment, the substrate surface may be pretreated to have a hydrophobic enhances surface to enhance the de-wetting of the substrate surface. The substrate may be exposed to a reducing gas to maximize dangling hydrogen bonds. The reducing agent may include silane (SiH₄), disilane (Si₂H₆), ammonia (NH₃), hydrazine (N₂H₄), diborane (B₂H₆), triethylborane (Et₃B), hydrogen (H₂), atomic hydrogen (H), plasmas thereof, radicals thereof, derivatives thereof, or combinations thereof. Other examples provide a degassing process or a pre-cleaning process to prevent out-gassing after depositing the metal layer. In another embodiment, the pretreatment process provides a nucleation surface or a seed surface on the substrate. In other embodiments, the nucleation surface or the seed surface is formed by an ALD process, a P3i flooding process, or a charge gun flooding process.

The tunnel dielectric layer may be formed on the substrate, preferably, on a pretreated surface of the substrate. In one embodiment, the tunnel dielectric layer may be formed of the substrate with a uniformity of less than about 0.5%, preferably, less than about 0.3%. Examples provide that the tunnel dielectric layer may be formed or deposited by a pulsed DC deposition process, a RF sputtering process, an electroless deposition process, an ALD process, a CVD process, or a PVD process.

Subsequent the deposition of the tunnel dielectric layer, the substrate may be exposed to a RTA process during the post-treatment process. Other post-treatment process include a doping process, a P3i flooding process, a CVD process, a laser anneal process, a flash anneal, or combinations thereof. In an alternative embodiment, a sacrificial capping layer may be deposited on the substrate during the post-treatment process. The sacrificial capping layer may be deposited by an electroless process, an ALD process, a CVD process, a PVD process, a spin-on process, or combinations thereof.

Embodiments provide that metallic nanocrystals 222, 322, and 422 may contain at least one metal such as platinum, palladium, nickel, iridium, ruthenium, cobalt, tungsten, tantalum, molybdenum, rhodium, gold, silicides thereof, nitrides thereof, carbides thereof, alloys thereof, or combinations thereof. The metal may be deposited by an electroless process, an electroplating process (ECP), an ALD process, a CVD process, a PVD process, or combinations thereof.

In one embodiment, the metallic nanocrystalline layers (e.g., nanocrystal layers 220, 320, and 420) may be exposed to a RTA to control the nanocrystalline size and size distribution. In one example, the metallic nanocrystalline layer is formed at a temperature within a range from about 300° C. to about 1,250° C., preferably, from about 400° C. to about 1,100° C., and more preferably, from about 500° C. to about 1,000° C. In one example, the metallic nanocrystalline layers (e.g., nanocrystal layers 220, 320, and 420) contain metallic nanocrystals (e.g., metallic nanocrystals 222, 322, and 422) having a nanocrystalline grain size within a range from about 0.5 nm to about 10 nm, preferably, from about 1 nm to about 5 nm, and more preferably, from about 2 nm to about 3 nm. In another example, the metallic nanocrystalline layers contain nanocrystals, such that about 80% by weight of the nanocrystals have a nanocrystalline grain size within a range from about 1 nm to about 5 nm, preferably, about 90% by weight of the nanocrystals have a nanocrystalline grain size within a range from about 1 nm to about 5 nm, more preferably, about 95% by weight of the nanocrystals have a nanocrystalline grain size within a range from about 1 nm to about 5 nm, and more preferably, about 97% by weight of the nanocrystals have a nanocrystalline grain size within a range from about 1 nm to about 5 nm, and more preferably, about 99% by weight of the nanocrystals have a nanocrystalline grain size within a range from about 1 nm to about 5 nm. In another embodiment, the metallic nanocrystal layers contain a nanocrystalline grain density distribution of about +/−3 grains per a gate area of about 35 nm by about 120 nm.

In one embodiment, the metallic nanocrystalline (MNC) layers (e.g., nanocrystal layers 220, 320, and 420) may contain about 100 nanocrystals (e.g., metallic nanocrystals 222, 322, and 422). The MNC layers may have a nanocrystalline density of about 1×10¹¹ cm⁻² or greater, preferably, about 1×10^{12 cm}⁻² or greater, and more preferably, about 5×10¹² cm⁻² or greater, and more preferably, about 1×10¹³ cm⁻² or greater. In one example, the MNC layers contain platinum and has a nanocrystalline density of at least about 5×10¹² cm⁻², preferably, about 8×10¹² cm⁻² or greater. In another example, the MNC layers contain ruthenium and has a nanocrystalline density of at least about 5×10¹² cm⁻², preferably, about 8×10¹² cm⁻² or greater. In another example, the MNC layers contain and has a nanocrystalline density of at least about 5×10¹² cm⁻², preferably, about 8×10¹² cm⁻² or greater.

In one embodiment, nanocrystals or nano-dots are used to form a MNC cell for flash memory containing metallic nanocrystals 222, 322, and 422. In one example, the MNC cell may be formed by exposing a substrate to a pretreatment process, forming a first dielectric layer, exposing the substrate to post-deposition process, forming a metallic nanocrystalline layer, and depositing a dielectric capping layer. Examples provide that the substrate may be examined by various metrological processes.

In another embodiment, the surface treatment or pretreatment may include nucleation control (“seed” nucleation sites) to assist in achieving a uniform nanocrystalline density and a narrow nanocrystalline size distribution. Examples provide vapor exposure by ALD or CVD processes, P3i flooding, charge gun flooding (electrons, or ions), CNT or Si fill di-electron probe for surface mod (“Si grass”), touching, electron treatment, metal vapor, and NIL templates.

In an alternative embodiment, a CVD oxide deposition process may be used as a single step to produce nanocrystals combined within a dielectric layer, such as a silicon oxide. In one example, nanocrystals are combined or mixed into TEOS so they are embedded into the film during the deposition on top of dielectric tunnel layer (e.g., silicon oxide). In another embodiment, the substrate surface may be exposed to localized heating by use of a laser and grating or by NIL templates.

In another embodiment, the sacrificial layer may be converted into islands (e.g., 2-3 nm diameters) on the substrate heating (e.g., RTA) or exposing the substrate to other treatments to form a template. Thereafter, the template may be used during a temptation. In one example, atomic layer etching may be used to form a nanocrystalline material.

In another embodiment, nanocrystals or nano-dots are used to form a MNC cell for flash memory. In one example, the MNC cell contains at least one metallic nanocrystalline layer between two dielectric layers, such as a lower dielectric layer (e.g., tunnel dielectric) and an upper dielectric layer (e.g., capping dielectric layer, top dielectric, or intermediate dielectric layer). The metallic nanocrystalline layer contains nanocrystals (e.g., metallic nanocrystals 222, 322, and 422) containing at least one metal, such as platinum, palladium, nickel, iridium, ruthenium, cobalt, tungsten, tantalum, molybdenum, rhodium, gold, silicides thereof, nitrides thereof, carbides thereof, alloys thereof, or combinations thereof. In one example, a nanocrystalline material comprises platinum, nickel, ruthenium, platinum-nickel alloy, or combinations thereof. In another example, a nanocrystalline material comprises by weight about 5% of platinum and about 95% of nickel.

In another embodiment, the MNC cell contains at least two metallic nanocrystalline layers between separated by an intermediate dielectric layer, and having a lower dielectric layer (e.g., tunnel dielectric) and an upper dielectric layer (e.g., capping dielectric layer or top dielectric layer). In another embodiment, the MNC cell contains at least three metallic nanocrystalline layers, each separated by an intermediate dielectric layer, and having a lower dielectric layer (e.g., tunnel dielectric) and an upper dielectric layer (e.g., capping dielectric layer or top dielectric layer).

In other embodiments, a method for forming a multi-layered metallic nanocrystalline material on a substrate is provided which includes exposing the substrate to a pretreatment process, forming a tunnel dielectric layer on the substrate, forming a plurality of bi-layers on the substrate, wherein each of the bi-layers comprises an intermediate dielectric layer deposited on a metallic nanocrystalline layer, and forming a dielectric capping layer on the plurality of bi-layers. In one example, the plurality of bi-layers may contain at least 10 metallic nanocrystalline layers and at least 10 intermediate dielectric layers. In another example, the plurality of bi-layers may contain at least 50 metallic nanocrystalline layers and at least 50 intermediate dielectric layers. In another example, the plurality of bi-layers may contain at least 100 metallic nanocrystalline layers and at least 100 intermediate dielectric layers.

In one example, a metallic nanocrystalline material is provided which includes a tunnel dielectric layer disposed on a substrate, a first metallic nanocrystalline layer disposed on the tunnel dielectric layer, a first intermediate dielectric layer disposed on the first metallic nanocrystalline layer, a second metallic nanocrystalline layer disposed on the first intermediate dielectric layer, a second intermediate dielectric layer disposed on the second metallic nanocrystalline layer, a third metallic nanocrystalline layer disposed on the second intermediate dielectric layer, and a dielectric capping layer disposed on the third metallic nanocrystalline layer.

In some embodiments, a lower dielectric layer (e.g., tunnel dielectric or bottom electrode) contains a dielectric material, such as silicon, silicon oxide, or derivatives thereof and an upper dielectric layer (e.g., capping dielectric layer, top dielectric, top electrode, or intermediate dielectric layer) contains a dielectric material, such as silicon, silicon nitride, silicon oxide, aluminum oxide, hafnium oxide, aluminum silicate, hafnium silicates, or derivatives thereof. In one embodiment, top dielectric layer 230 or intermediate dielectric layers 330 and 430 contains a dielectric material, such as silicon, silicon nitride, silicon oxide, silicon oxynitride, aluminum oxide, hafnium oxide, aluminum silicate, hafnium silicate, hafnium silicon oxynitride, zirconium oxide, zirconium silicate, derivatives thereof, or combinations thereof. In one example, a dielectric material, such as a gate oxide dielectric material, may be formed by an in-situ steam generation (ISSG) process, a water vapor generation (WVG) process, or a rapid thermal oxide (RTO) process.

Apparatuses and processes, including the ISSG, WVG, and RTO processes, that may be used to form the dielectric layers and materials are further described in commonly assigned U.S. Ser. No. 11/127,767, filed May 12, 2005, and published as US 2005-0271813, U.S. Ser. No. 10/851,514, filed May 21, 2004, and published as US 2005-0260357, U.S. Ser. No. 11/223,896, filed Sep. 9, 2005, and published as US 2006-0062917, U.S. Ser. No. 10/851,561, filed May 21, 2004, and published as US 2005-0260347, and commonly assigned U.S. Pat. Nos. 6,846,516, 6,858,547, 7,067,439, 6,620,670, 6,869,838, 6,825,134, 6,905,939, and 6,924,191, which are herein incorporated by reference in their entirety.

In one embodiment, metallic nanocrystalline layers containing nanocrystals (e.g., metallic nanocrystals 222, 322, and 422) may be formed by depositing at least one metal layer onto a substrate and exposing the substrate to an annealing process to form nanocrystals containing at least one metal from the metal layer. The metal layer may be formed or deposited by a PVD process, an ALD process, a CVD process, an electroless deposition process, an ECP process, or combinations thereof. The metal layer may be deposited to a thickness of about 100 Å or less, such as within a range from about 3 Å to about 50 Å, preferably, from about 4 Å to about 30 Å, and more preferably, from about 5 Å to about 20 Å. Examples of annealing processes include RTP, flash annealing, and laser annealing.

In one embodiment, the substrate (e.g., substrate 202, 302, and 402) may be positioned into an annealing chamber and exposed to a post deposition annealing (PDA) process. The CENTURA® RADIANCE® RTP chamber, available from Applied Materials, Inc., located in Santa Clara, Calif., is an annealing chamber that may be used during the PDA process. The substrate may be heated to a temperature within a range from about 300° C. to about 1,250° C., or from about 400° C. to about 1,100° C., or from about 500° C. to about 1,000° C., for example, about 1,100° C.

In another embodiment, metallic nanocrystalline layers containing nanocrystals (e.g., metallic nanocrystals 222, 322, and 422) may be formed by depositing, forming, or distributing satellite metallic nano-dots onto the substrate. The substrate may be pre-heated to a predetermined temperature, such as to a temperature within a range from about 300° C. to about 1,250° C., or from about 400° C. to about 1,100° C., or from about 500° C. to about 1,000° C. The metallic nano-dots may be preformed and deposited or distributed onto the substrate by evaporating a liquid suspension of the metallic nano-dots. The metallic nano-dots may be crystalline or amorphous, but will be recrystallized by the pre-heated substrate to form metallic nanocrystals within a metallic nanocrystalline layer.

The metallic nanocrystalline layers (e.g., nanocrystal layers 220, 320, and 420) contain nanocrystals (e.g., metallic nanocrystals 222, 322, and 422) which contain at least one metal, such as platinum, palladium, nickel, iridium, ruthenium, cobalt, tungsten, tantalum, molybdenum, rhodium, gold, silicides thereof, nitrides thereof, carbides thereof, alloys thereof, or combinations thereof. In one example, the nanocrystalline material contains platinum, nickel, ruthenium, platinum-nickel alloy, or combinations thereof. In another example, the nanocrystalline material contains ruthenium or ruthenium alloys. In another example, the nanocrystalline material contains platinum or platinum alloys.

Apparatuses and processes that may be used to form the metal layers and materials are further described in commonly assigned U.S. Ser. No. 10/443,648, filed May 22, 2003, and published as US 2005-0220998, U.S. Ser. No. 10/634,662, filed Aug. 4, 2003, and published as US 2004-0105934, U.S. Ser. No. 10/811,230, filed Mar. 26, 2004, and published as US 2004-0241321, U.S. Ser. No. 60/714580, filed Sep. 6, 2005, and in commonly assigned U.S. Pat. Nos. 6,936,538, 6,620,723, 6,551,929, 6,855,368, 6,797,340, 6,951,804, 6,939,801, 6,972,267, 6,596,643, 6,849,545, 6,607,976, 6,702,027, 6,916,398, 6,878,206, and 6,936,906, which are herein incorporated by reference in their entirety.

In other embodiments, besides flash memory applications, nanocrystals or nano-dots are used as catalysts for fuel cells, batteries, or polymerization reactions and within catalytic converters, photovoltaic cells, light emitting devices, or energy scavenger devices.

While the foregoing is directed to embodiments of the invention, other and further embodiments of the invention may be devised without departing from the basic scope thereof, and the scope thereof is determined by the claims that follow.

1. A method for forming a metallic nanocrystalline material on a substrate, comprising:
exposing a substrate to a pretreatment process;
forming a tunnel dielectric layer on the substrate;
exposing the substrate to a post-treatment process;
forming a metallic nanocrystalline layer on the tunnel dielectric layer; and
forming a dielectric capping layer on the metallic nanocrystalline layer.

2. The method of claim 1, wherein the metallic nanocrystalline layer comprises ruthenium or a ruthenium alloy.

3. The method of claim 2, wherein a plurality of additional metallic nanocrystalline layers and additional dielectric capping layers are sequentially formed thereon.

4. The method of claim 3, wherein the plurality of additional metallic nanocrystalline layers and additional dielectric capping layers comprises at least 10 additional metallic nanocrystalline layers and at least 10 additional dielectric capping layers.

5. The method of claim 4, wherein the plurality of additional metallic nanocrystalline layers and additional dielectric capping layers comprises at least 50 additional metallic nanocrystalline layers and at least 50 additional dielectric capping layers.

6. The method of claim 5, wherein the plurality of additional metallic nanocrystalline layers and additional dielectric capping layers comprises at least 100 additional metallic nanocrystalline layers and at least 100 additional dielectric capping layers.

7. The method of claim 1, wherein the metallic nanocrystalline layer comprises a metal selected from the group consisting of platinum, palladium, nickel, iridium, ruthenium, cobalt, tungsten, tantalum, molybdenum, rhodium, gold, silicides thereof, nitrides thereof, carbides thereof, alloys thereof, and combinations thereof.

8. The method of claim 2, wherein the pretreatment process provides a hydrophobic surface on the substrate.

9. The method of claim 8, wherein the hydrophobic surface is formed by exposing the substrate to a reducing agent.

10. The method of claim 9, wherein the reducing agent is selected from the group consisting of silane, disilane, ammonia, hydrazine, diborane, triethylborane, hydrogen, atomic hydrogen, plasmas thereof, derivatives thereof, and combinations thereof.

11. The method of claim 1, wherein the substrate is exposed to a degassing process during the pretreatment process.

12. The method of claim 1, wherein the pretreatment process provides a nucleation surface or a seed surface on the substrate and the nucleation surface or the seed surface is formed by a process selected by the group consisting of atomic layer deposition, P3i flooding, charge gun flooding, and combinations thereof.

13. The method of claim 2, wherein the tunnel dielectric layer is formed on the substrate with a uniformity of less than about 0.5%.

14. The method of claim 2, wherein the tunnel dielectric layer is formed by a process selected from the group consisting of pulsed DC deposition, RF sputtering, electroless deposition, atomic layer deposition, chemical vapor deposition, physical vapor deposition, and combinations thereof.

15. The method of claim 2, wherein the substrate, during the post-treatment process, is exposed to a process selected from the group consisting of rapid thermal annealing, laser anneal, doping, P3i flooding, chemical vapor deposition, and combinations thereof.

16. The method of claim 1, wherein a sacrificial capping layer is deposited on the substrate during the post-treatment process.

17. The method of claim 16, wherein the sacrificial capping layer is deposited by a process selected from the group consisting of spin-on process, electroless deposition, atomic layer deposition, chemical vapor deposition, physical vapor deposition, and combinations thereof.

18. The method of claim 1, wherein the metallic nanocrystalline layer is exposed to a rapid thermal annealing process to control the nanocrystalline size and size distribution.

19. The method of claim 18, wherein the metallic nanocrystalline layer is formed at a temperature within a range from 300° C. to about 1,250° C. during the rapid thermal annealing process.

20. The method of claim 19, wherein the temperature is within a range from 500° C. to about 1,000° C.

21. The method of claim 1, wherein the metallic nanocrystalline layer comprises nanocrystals and at least about 80% by weight of the nanocrystals have a nanocrystalline grain size within a range from about 1 nm to about 5 nm.

22. The method of claim 21, wherein at least about 90% by weight of the nanocrystals have the nanocrystalline grain size within the range from about 1 nm to about 5 nm.

23. The method of claim 22, wherein at least about 95% by weight of the nanocrystals have the nanocrystalline grain size within the range from about 1 nm to about 5 nm.

24. The method of claim 23, wherein about 99% by weight of the nanocrystals have the nanocrystalline grain size within the range from about 1 nm to about 5 nm.

25. The method of claim 1, wherein the metallic nanocrystalline layer comprises a nanocrystalline density of at least about 5×10¹² cm⁻².

26. The method of claim 25, wherein the nanocrystalline density is at least about 8×10¹² cm⁻².

27. The method of claim 25, wherein the metallic nanocrystalline layer comprises a metal selected from the group consisting of platinum, ruthenium, nickel, alloys thereof, and combinations thereof.

28. A method for forming a multi-layered metallic nanocrystalline material on a substrate, comprising:
exposing a substrate to a pretreatment process;
forming a tunnel dielectric layer on the substrate;
forming a first metallic nanocrystalline layer on the tunnel dielectric layer;
forming an intermediate dielectric layer on the first metallic nanocrystalline layer;
forming a second metallic nanocrystalline layer on the intermediate dielectric layer; and
forming a dielectric capping layer on the second metallic nanocrystalline layer.

29. The method of claim 28, wherein the first metallic nanocrystalline layer and the second metallic nanocrystalline layer each independently comprises a metal selected from the group consisting of platinum, palladium, nickel, iridium, ruthenium, cobalt, tungsten, tantalum, molybdenum, rhodium, gold, suicides thereof, nitrides thereof, carbides thereof, alloys thereof, and combinations thereof.

30. The method of claim 28, wherein the first metallic nanocrystalline layer and the second metallic nanocrystalline layer comprise ruthenium or a ruthenium alloy.

31. A method for forming a multi-layered metallic nanocrystalline material on a substrate, comprising:
exposing a substrate to a pretreatment process;
forming a tunnel dielectric layer on the substrate;
forming a plurality of bi-layers on the substrate, wherein each of the bi-layers comprises an intermediate dielectric layer deposited on a metallic nanocrystalline layer; and
forming a dielectric capping layer on the plurality of bi-layers.

32. The method of claim 31, wherein the metallic nanocrystalline layers comprise ruthenium or a ruthenium alloy.

33. The method of claim 32, wherein the plurality of bi-layers comprises at least 10 metallic nanocrystalline layers and at least 10 intermediate dielectric layers.

34. The method of claim 33, wherein the plurality of bi-layers comprises at least 50 metallic nanocrystalline layers and at least 50 intermediate dielectric layers.

35. The method of claim 34, wherein the plurality of bi-layers comprises at least 100 metallic nanocrystalline layers and at least 100 intermediate dielectric layers.

36. The method of claim 31, wherein the metallic nanocrystalline layers comprise a metal selected from the group consisting of platinum, ruthenium, nickel, alloys thereof, and combinations thereof.

37. A metallic nanocrystalline material, comprising:
a tunnel dielectric layer disposed on a substrate;
a metallic nanocrystalline layer disposed on the tunnel dielectric layer;
a dielectric capping layer disposed on the metallic nanocrystalline layer; and
a control gate layer disposed on the dielectric capping layer.

38. The metallic nanocrystalline material of claim 37, wherein the metallic nanocrystalline layer comprises a nanocrystalline density of at least about 5×10¹² cm⁻².

39. The metallic nanocrystalline material of claim 38, wherein the nanocrystalline density is at least about 8×10¹² cm⁻².

40. The metallic nanocrystalline material of claim 38, wherein the metallic nanocrystalline layer comprises a metal selected from the group consisting of platinum, palladium, nickel, iridium, ruthenium, cobalt, tungsten, tantalum, molybdenum, rhodium, gold, silicides thereof, nitrides thereof, carbides thereof, alloys thereof, and combinations thereof.

41. A metallic nanocrystalline material, comprising:
a tunnel dielectric layer disposed on a substrate;
a first metallic nanocrystalline layer disposed on the tunnel dielectric layer;
an intermediate dielectric layer disposed on the first metallic nanocrystalline layer;
a second metallic nanocrystalline layer disposed on the intermediate dielectric layer; and
a dielectric capping layer disposed on the second metallic nanocrystalline layer.

42. A metallic nanocrystalline material, comprising:
a tunnel dielectric layer disposed on a substrate;
a first metallic nanocrystalline layer disposed on the tunnel dielectric layer;
a first intermediate dielectric layer disposed on the first metallic nanocrystalline layer;
a second metallic nanocrystalline layer disposed on the first intermediate dielectric layer;
a second intermediate dielectric layer disposed on the second metallic nanocrystalline layer;
a third metallic nanocrystalline layer disposed on the second intermediate dielectric layer; and
a dielectric capping layer disposed on the third metallic nanocrystalline layer.
